(19) United States
(12) Patent Application Publication
(10) Pub. No.: US 2026/0165046 A1
(43) Pub. Date: Jun. 11, 2026

(54) PLASMA TREATMENT PROCESSES FOR SELECTIVE DEPOSITION

(71) Applicant: Applied Materials, Inc., Santa Clara, CA (US)

(72) Inventors: Ligang Gao, Chandler, AZ (US); Vahid Ghodsi Karbasdehi, Chandler, AZ (US); Aniruddh Shekhawat, Tempe, AZ (US); Karthik Colinjivadi, Dublin, CA (US)

(73) Assignee: Applied Materials, Inc., Santa Clara, CA (US)

(21) Appl. No.: 18/971,241

(22) Filed: Dec. 6, 2024

(51) Int. Cl. H01L 21/02; C23C 16/02; C23C 16/04; C23C 16/34; C23C 16/455

(52) U.S. Cl. CPC H10P 14/6514; C23C 16/0245; C23C 16/04; C23C 16/34; C23C 16/45553; H10P 14/6339; H10P 14/69433

(57) ABSTRACT

Plasma treatment processes for selective deposition that are employed in the manufacture of electronic devices are described. Exemplary methods include selectively depositing a metal nitride layer on a first surface comprising one or more of silicon, silicon oxynitride, silicon nitride, tungsten, or titanium aluminum carbide, over a second surface comprising a metal oxide, such as, for example, one or more of silicon oxide, aluminum oxide, hafnium oxide, or zirconium oxide. The first surface and the second surface are treated with a plasma prior to selectively depositing the metal nitride layer.

### TECHNICAL FIELD

Embodiments of the disclosure generally relate to the manufacture of electronic devices. More particularly, embodiments of the disclosure are directed to plasma treatment processes employed in the manufacture of electronic devices.

### BACKGROUND

The semiconductor processing industry continues to strive for larger production yields while increasing the uniformity of layers deposited on substrates having larger surface areas. These same factors in combination with new materials also provide higher integration of circuits per unit area of the substrate. As circuit integration increases, the need for greater uniformity and process control regarding layer thickness rises. As a result, various technologies have been developed to deposit layers on substrates in a cost-effective manner, while maintaining control over the characteristics of the layer.

The semiconductor industry faces many challenges in the pursuit of device miniaturization which involves rapid scaling of nanoscale features. Such issues include the introduction of complex fabrication steps such as multiple lithography steps and integration of high-performance materials. To maintain the cadence of device miniaturization, selective deposition, for example, has shown promise as it has the potential to remove costly lithographic steps by simplifying integration schemes.

Selective deposition of materials can be accomplished in a variety of ways. A chemical precursor may react selectively with one surface relative to another surface (e.g., metallic or dielectric). Process parameters such as pressure, substrate temperature, precursor partial pressures, and/or gas flows can be tuned to modulate the chemical kinetics of a particular surface reaction. Another possible scheme involves surface treatments that can be used to activate or deactivate a surface of interest to an incoming deposition precursor.

Many traditional inhibitors must be chosen based on the chemical nature of the composition of the substrate surface and/or the composition of a film already present on the substrate surface. For example, some inhibitors are specific to metal vs. dielectric surface or to specific reactive groups of the substrate surface.

Thus, there remains an ongoing need in the art for methods that can achieve selective deposition while having minimal or no dependence on the film underneath.

### SUMMARY

One or more embodiments of the disclosure are directed to a method comprising: selectively depositing a metal nitride layer on a first surface comprising one or more of silicon, silicon oxynitride, silicon nitride, tungsten, or titanium aluminum carbide, over a second surface comprising one or more of silicon oxide, aluminum oxide, hafnium oxide, or zirconium oxide, wherein the first surface and the second surface are treated with a plasma prior to selectively depositing the metal nitride layer.

Some embodiments are directed to a method comprising: selectively depositing a metal nitride layer on a substrate having at least one feature defining a gap having sidewalls and a bottom surface, the sidewalls comprising one or more of silicon oxide, aluminum oxide, hafnium oxide, or zirconium oxide, the bottom surface comprising one or more of silicon, silicon oxynitride, silicon nitride, tungsten, or titanium aluminum carbide, wherein the substrate is treated with a plasma prior to selectively depositing the metal nitride layer, and the metal nitride layer is selectively deposited on the bottom surface over the sidewalls.

Some embodiments are directed to a method comprising: selectively depositing a metal nitride layer on a substrate having at least one feature defining a gap having sidewalls and a bottom surface, the sidewalls comprising one or more of silicon, silicon oxynitride, silicon nitride, tungsten, or titanium aluminum carbide, the bottom surface comprising one or more of silicon oxide, aluminum oxide, hafnium oxide, or zirconium oxide, wherein the substrate is treated with a plasma prior to selectively depositing the metal nitride layer, and the metal nitride layer is selectively deposited on the sidewalls over the bottom surface.

Further embodiments of the disclosure are directed to a method comprising: selectively depositing a metal nitride layer on a substrate comprising a plurality of layers, the plurality of layers including a first layer comprising one or more of silicon oxide, aluminum oxide, hafnium oxide, or zirconium oxide, a second layer comprising one or more of silicon, silicon oxynitride, silicon nitride, tungsten, or titanium aluminum carbide adjacent the first layer, a third layer comprising one or more of silicon, silicon oxynitride, silicon nitride, tungsten, or titanium aluminum carbide adjacent the second layer, a fourth layer comprising one or more of silicon, silicon oxynitride, silicon nitride, tungsten, or titanium aluminum carbide adjacent the third layer, a fifth layer comprising one or more of silicon oxide, aluminum oxide, hafnium oxide, or zirconium oxide adjacent the fourth layer, and a sixth layer comprising one or more of silicon, silicon oxynitride, silicon nitride, tungsten, or titanium aluminum carbide adjacent the fifth layer, wherein the substrate is treated with a plasma prior to selectively depositing the metal nitride layer, and the metal nitride layer is selectively deposited on the second layer, the third layer, the fourth layer, and the sixth layer over the first layer and the fifth layer.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A illustrates a process flow diagram of a method in accordance with one or more embodiments of the disclosure;

FIG. 1B illustrates a schematic cross-sectional view of a substrate including a first surface and a second surface in accordance with one or more embodiments of the disclosure;

FIG. 1C illustrates a schematic cross-sectional view of treating the substrate of FIG. 1B with a plasma in accordance with one or more embodiments of the disclosure;

FIG. 1D illustrates a schematic cross-sectional view of the substrate with a treated first surface and a treated second surface after treatment with the plasma in accordance with one or more embodiments of the disclosure;

FIG. 1E illustrates a schematic cross-sectional view of a metal nitride layer selectively deposited on the treated first surface in accordance with one or more embodiments of the disclosure;

FIG. 2A illustrates a process flow diagram of a method in accordance with one or more embodiments of the disclosure;

FIG. 2B illustrates a cross-sectional schematic view of a substrate including at least one feature defining a gap having sidewalls and a bottom surface in accordance with one or more embodiments of the disclosure;

FIG. 2C illustrates a cross-sectional schematic view of the gap after treating the substrate with a plasma and selectively depositing a metal nitride layer on the bottom surface in accordance with one or more embodiments of the disclosure;

FIG. 2D illustrates a cross-sectional schematic view of the gap after treating the substrate with a plasma and selectively depositing a metal nitride layer on the sidewalls in accordance with one or more embodiments of the disclosure;

FIG. 3A illustrates a process flow diagram of a method in accordance with one or more embodiments of the disclosure;

FIG. 3B illustrates a schematic cross-sectional view of a substrate including a plurality of layers in accordance with one or more embodiments of the disclosure;

FIG. 3C illustrates a schematic cross-sectional view of treating the substrate of FIG. 3B with a plasma in accordance with one or more embodiments of the disclosure;

FIG. 3D illustrates a schematic cross-sectional view of the substrate with a plurality of treated layers after treatment with the plasma in accordance with one or more embodiments of the disclosure; and

FIG. 3E illustrates a schematic cross-sectional view of a selectively deposited metal nitride layer in accordance with one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15%, or less, of the numerical value. For example, a value differing by ±14%, ±10%, ±5%, ±2%, or ±1%, would satisfy the definition of about.

Spatially relative terms, such as “beneath,” “below,” “lower,” “above,” “upper” and the like, may be used herein for ease of description to describe one element's relationship to another element(s) or feature(s) as illustrated in the Figures. It will be understood that the spatially relative terms are intended to encompass different orientations of the substrate in use or operation in addition to the orientation depicted in the Figures. For example, if the substrate in the Figures is turned over, elements described as “below” or “beneath” other elements would then be oriented “above” the other elements. Thus, the exemplary term “below” may encompass both an orientation of above and below. The substrate may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein.

All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments,” “some embodiments,” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in some embodiments,” “in one embodiment,” or “in an embodiment” in various places throughout this specification are not necessarily referring to the same embodiment of the disclosure. In one or more embodiments, the particular features, structures, materials, or characteristics are combined in any suitable manner.

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate, unless the context clearly indicates otherwise. Additionally, reference to “depositing on” or “forming on” a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. In some embodiments, the substrate comprises one or more of doped or undoped crystalline silicon (Si), doped or undoped crystalline silicon germanium (SiGe), doped or undoped amorphous silicon (Si), or doped or undoped amorphous silicon germanium (SiGe).

Substrates may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

The term “on” indicates that there is direct contact between elements. The term “directly on” indicates that there is direct contact between elements with no intervening elements.

As used herein, the term “in situ” refers to processes that are all performed in the same processing chamber or within different processing chambers that are connected as part of an integrated processing system, such that each of the processes are performed without an intervening vacuum break. As used herein, the term “ex situ” refers to processes that are performed in at least two different processing chambers such that one or more of the processes are performed with an intervening vacuum break. In some embodiments, processes are performed without breaking vacuum or without exposure to ambient air.

As used herein, the terms “precursor,” “reactant,” “reactive gas,” “reactive species,” and the like are used interchangeably to refer to any gaseous species that can react with the substrate surface.

As used herein, the term “chemical vapor deposition” refers to the exposure of at least one reactive species to deposit a layer of material on the substrate surface. In some embodiments, the chemical vapor deposition (CVD) process comprises mixing the two or more reactive species in the processing chamber to allow gas phase reactions of the reactive species and deposition. In some embodiments, the CVD process comprises exposing the substrate surface to two or more reactive species simultaneously. In some embodiments, the CVD process comprises exposing the substrate surface to a first reactive species continuously with an intermittent exposure to a second reactive species. In some embodiments, the substrate surface undergoes the CVD reaction to deposit a layer having a predetermined thickness. In the CVD process, the layer can be deposited in one exposure to the mixed reactive species or can be multiple exposures to the mixed reactive species with purges between. In some embodiments, the substrate surface is exposed to the first reactive species and the second reactive species substantially simultaneously.

As used herein, “substantially simultaneously” means that most of the duration of the first reactive species exposure overlaps with the second reactive species exposure.

As used herein, the term “purging” includes any suitable purge process that removes unreacted precursor, reaction products and by-products from the process region. The suitable purge process includes moving the substrate through a gas curtain to a portion or sector of the processing region that contains none or substantially none of the reactant. In one or more embodiments, purging the processing chamber comprises applying a vacuum. In some embodiments, purging the processing region comprises flowing a purge gas over the substrate. In some embodiments, the purge process comprises flowing an inert gas. In one or more embodiments, the purge gas is selected from one or more of nitrogen (N₂), helium (He), and argon (Ar). In some embodiments, the first reactive species is purged from the reaction chamber for a time duration in a range of from 0.1 seconds to 30 seconds, for example, before exposing the substrate to the second reactive species.

“Cyclical deposition” or “atomic layer deposition” (ALD) refers to the sequential exposure of two or more reactive species to deposit a layer of material on a substrate surface. The substrate, or portion of the substrate, is exposed separately to the two or more reactive species which are introduced into a reaction zone of a processing chamber. In a time-domain ALD process, exposure to each reactive species is separated by a time delay to allow each compound to adhere and/or react on the substrate surface and then be purged from the processing chamber. These reactive species are said to be exposed to the substrate sequentially. In a spatial ALD process, different portions of the substrate surface, or material on the substrate surface, are exposed simultaneously to the two or more reactive species so that any given point on the substrate is substantially not exposed to more than one reactive species simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive species or reaction by-products from the reaction zone. Alternatively, the purge gas may flow continuously throughout the deposition process so that only the purge gas flows during the time delay between pulses of reactive species. The reactive species are alternatively pulsed until a desired layer or layer thickness is formed on the substrate surface. In either scenario, the ALD process of pulsing compound A, purge gas, compound B and purge gas is a cycle. A cycle can start with either compound A or compound B and continue the respective order of the cycle until achieving a layer with the predetermined thickness.

One or more of the layers deposited on the substrate or substrate surface are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

Generally, front-end of line (FEOL) refers to the first portion of integrated circuit fabrication, including transistor fabrication, middle-of-line (MOL) connects the transistor and interconnect parts of a chip using a series of contact structures, and back-end of line (BEOL) refers to a series of process steps after transistor fabrication through completion of a wafer. The methods according to one or more embodiments of the disclosure can advantageously be used in MOL and/or BEOL processes.

One or more embodiments of the disclosure are directed to plasma treatment processes. Some embodiments of the disclosure are directed to plasma treatment processes for selective deposition that are employed in the manufacture of electronic devices. Some embodiments of the disclosure are directed to plasma treatment processes for selective deposition that are employed in the manufacture of, for example, logic devices.

One or more embodiments of the disclosure employ plasma treatment processes configured to treat a surface and suppress or prevent subsequent deposition on that surface.

Embodiments of the disclosure advantageously provide methods that can achieve selective deposition while having minimal or no dependence on the film underneath. Some embodiments advantageously provide methods that can achieve selective deposition without the use of an inhibitor while having minimal or no dependence on the film underneath. Some embodiments advantageously provide methods that can achieve selective deposition without the use of an inhibitor as a chemical free and high throughput process.

One or more embodiments of the disclosure are directed to a method comprising: selectively depositing a metal nitride layer on a first surface comprising one or more of silicon, silicon oxynitride, silicon nitride, tungsten, or titanium aluminum carbide, over a second surface comprising one or more of silicon oxide, aluminum oxide, hafnium oxide, or zirconium oxide, wherein the first surface and the second surface are treated with a plasma prior to selectively depositing the metal nitride layer.

Some embodiments are directed to a method comprising: selectively depositing a metal nitride layer on a substrate having at least one feature defining a gap having sidewalls and a bottom surface, the sidewalls comprising one or more of silicon oxide, aluminum oxide, hafnium oxide, or zirconium oxide, the bottom surface comprising one or more of silicon, silicon oxynitride, silicon nitride, tungsten, or titanium aluminum carbide, wherein the substrate is treated with a plasma prior to selectively depositing the metal nitride layer, and the metal nitride layer is selectively deposited on the bottom surface over the sidewalls.

Some embodiments are directed to a method comprising: selectively depositing a metal nitride layer on a substrate having at least one feature defining a gap having sidewalls and a bottom surface, the sidewalls comprising one or more of silicon, silicon oxynitride, silicon nitride, tungsten, or titanium aluminum carbide, the bottom surface comprising one or more of silicon oxide, aluminum oxide, hafnium oxide, or zirconium oxide, wherein the substrate is treated with a plasma prior to selectively depositing the metal nitride layer, and the metal nitride layer is selectively deposited on the sidewalls over the bottom surface.

Further embodiments of the disclosure are directed to a method comprising: selectively depositing a metal nitride layer on a substrate comprising a plurality of layers, the plurality of layers including a first layer comprising one or more of silicon oxide, aluminum oxide, hafnium oxide, or zirconium oxide, a second layer comprising one or more of silicon, silicon oxynitride, silicon nitride, tungsten, or titanium aluminum carbide adjacent the first layer, a third layer comprising one or more of silicon, silicon oxynitride, silicon nitride, tungsten, or titanium aluminum carbide adjacent the second layer, a fourth layer comprising one or more of silicon, silicon oxynitride, silicon nitride, tungsten, or titanium aluminum carbide adjacent the third layer, a fifth layer comprising one or more of silicon oxide, aluminum oxide, hafnium oxide, or zirconium oxide adjacent the fourth layer, and a sixth layer comprising one or more of silicon, silicon oxynitride, silicon nitride, tungsten, or titanium aluminum carbide adjacent the fifth layer, wherein the substrate is treated with a plasma prior to selectively depositing the metal nitride layer, and the metal nitride layer is selectively deposited on the second layer, the third layer, the fourth layer, and the sixth layer over the first layer and the fifth layer.

Some embodiments are directed to a method comprising: selectively depositing a metal nitride layer on a substrate comprising a plurality of layers, the plurality of layers including a first layer comprising silicon oxide, a second layer comprising silicon oxynitride adjacent the first layer, a third layer comprising tungsten adjacent the second layer, a fourth layer comprising silicon oxynitride adjacent the third layer, a fifth layer comprising silicon oxide adjacent the fourth layer, and a sixth layer comprising silicon nitride adjacent the fifth layer, wherein the substrate is treated with a plasma prior to selectively depositing the metal nitride layer, and the metal nitride layer is selectively deposited on the second layer, the third layer, the fourth layer, and the sixth layer over the first layer and the fifth layer.

It has been found that depositing a metal nitride layer, using deposition techniques known in the art, on a substrate including, for example, a first surface comprising one or more of silicon, silicon oxynitride, silicon nitride, tungsten, or titanium aluminum carbide and a second surface comprising one or more of silicon oxide, aluminum oxide, hafnium oxide, or zirconium oxide forms the metal nitride layer on the first surface and the second surface when the plasma treatment processes described herein are not performed.

Some embodiments are directed to plasma treatment processes (i.e., surface treatments) that can be used to activate or deactivate a surface of interest to an incoming deposition precursor. Some embodiments are directed to plasma treatment processes (i.e., surface treatments) that can be used to deactivate a metal oxide surface, such as, for example, a silicon oxide surface, to an incoming deposition precursor, i.e., a metallic precursor and/or a nitrogen-containing reactant to prevent formation of a metal nitride layer thereon.

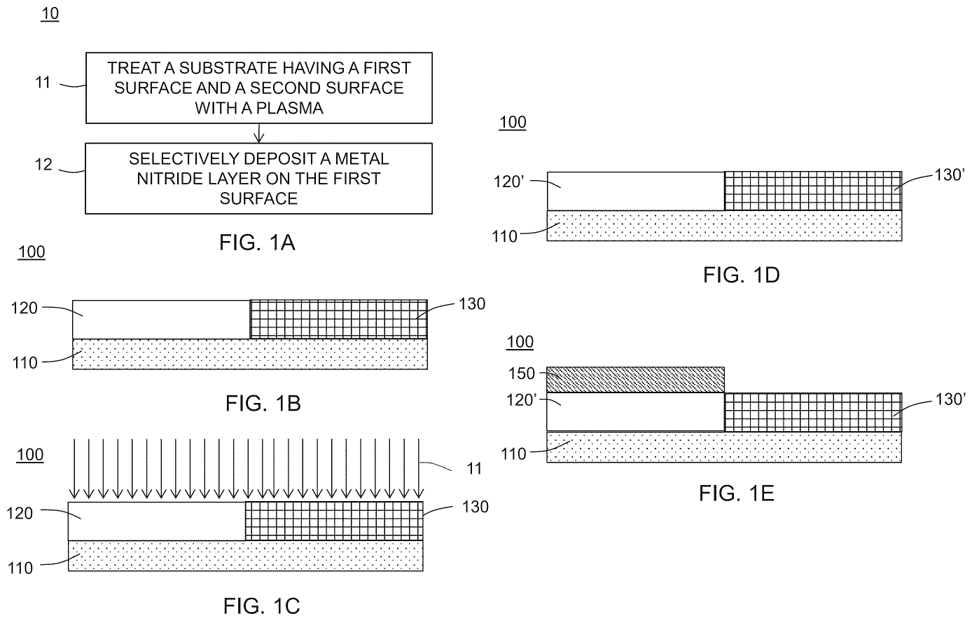

The plasma treatment processes for selective deposition are described herein with reference to FIGS. 1A-1E, 2A-2D, and 3A-3E.

FIG. 1A illustrates a process flow diagram of a method 10. FIGS. 1B-1E illustrate stages of processing a substrate 110 in accordance with the method 10.

In one or more embodiments, the method 10 comprises, at operation 11, treating the substrate 110 including a first surface 120 comprising one or more of silicon, silicon oxynitride, silicon nitride, tungsten, or titanium aluminum carbide, and a second surface 130 comprising one or more metal oxides (shown in FIG. 1B).

In some embodiments, the first surface 120 comprises silicon. In some more embodiments, the second surface 130 comprises one or more of silicon oxide, aluminum oxide, hafnium oxide, or zirconium oxide. In one or more embodiments, the second surface 130 comprises silicon oxide. Operation 11 is denoted by the arrows in FIG. 1C.

With reference to FIGS. 1A-1E, treating the substrate 110 (e.g., the first surface 120 and the second surface 130) in accordance with operation 11 forms a treated first surface 120′ and a treated second surface 130′.

In some embodiments, the plasma comprises, consists essentially of, or consists of one or more of hydrogen (H₂), helium (He), argon (Ar), carbon tetrafluoride (CF₄), nitrogen trifluoride (NF₃), trifluoromethane (CHF₃), chlorine trifluoride (ClF₃), difluoromethane (CH₂F₂), hexafluoro-1,3-butadiene (C₄F₆), sulfur hexafluoride (SF₆), octafluorocyclobutane (C₄F₈), chlorine (Cl₂), boron trichloride (BCl₃), bromotrifluoromethane (CF₃Br), hydrogen bromide (HBr), or ammonia (NH₃).

In some embodiments, the plasma is configured to remove native oxides from the first surface 120 to form the treated first surface 120′. In some embodiments, the plasma is configured to remove native oxides from the second surface 130 to form the treated second surface 130′.

In some embodiments, keeping the plasma treatment process (operation 11) under vacuum ensures that no oxide is introduced/formed on the substrate 110 during the method 10.

It has been advantageously found that treating the second surface 130 with the plasma in accordance with operation 11 (to form the treated second surface 130′) is configured to substantially prevent deposition of metal nitride on the treated second surface 130′. As used herein, the term “substantially prevent deposition” means that the treated second surface 130′ includes a metal nitride layer having a thickness of less than or equal to 5 Angstroms, less than or equal to 4 Angstroms, less than or equal to 3 Angstroms, less than or equal to 2 Angstroms, less than or equal to 1 Angstrom, less than or equal to 0.5 Angstroms, or less than or equal to 0.1 Angstroms thereon. In some embodiments, treating the second surface 130 with the plasma in accordance with operation 11 (to form the treated second surface 130′) is configured to prevent deposition of a metal nitride on the treated second surface 130′.

In accordance with operation 11, the substrate 110 may be treated at any suitable processing conditions, and the processing conditions may vary based upon the application in which the substrate 110 is used.

In one or more embodiments, in accordance with operation 11 of the method 10, the plasma is generated by a remote plasma source (RPS), capacitively coupled plasma (CCP) source, inductively coupled plasma (ICP) source, or a microwave plasma source.

The plasma can be generated at any suitable source power. In some embodiments, the plasma is generated at a source power in a range of from 100 watts to 1,500 watts. In some embodiments, a bias power in a range of from 0 watts to 500 watts is applied.

The substrate 110 may be treated at any suitable temperature during operation 11. In one or more embodiments, the first surface 120 and the second surface 130 are treated with the plasma at a first temperature for a first time period, followed by a second temperature for a second time period. In one or more embodiments, the second temperature is greater than the first temperature. In one or more embodiments, the first temperature is in a range of from 20° C. to 50° C. In one or more embodiments, the second temperature is in a range of from 90° C. to 200° C.

In one or more embodiments, the treatment process of operation 11 comprises a two-step process. The two-step process includes a first step in which the first surface 120 and the second surface 130 are treated with the plasma at a first temperature for a first time period. In some embodiments, the first temperature is in a range of from 20° C. to 50° C. and the first time period is in a range of from 5 seconds to 5 minutes. The two-step process includes a second step, performed after the first step, in which the first surface 120 and the second surface 130 are treated with the plasma at a second temperature for a second time period. In some embodiments, the second temperature is in a range of from 90° C. to 200° C. and the second time period is in a range of from 10 seconds to 10 minutes.

The two-step process of operation 11 can be performed in any suitable sequence. The two-step process of operation 11 can be repeated any suitable number of times. In one or more embodiments, the first step is performed for a portion of time within the first time period, then the second step is performed for a portion of time within the second period. The substrate 110 may be treated for any suitable duration of time during operation 11. In one or more embodiments, the substrate 110 is treated for a time period in a range of from 2 minutes to 20 minutes. In one or more embodiments, the time period in the range of from 2 minutes to 20 minutes includes the two-step process. Accordingly, for example, the first step can be performed for a portion of time within the first time period, followed by the second step for a portion of time within the second period. Stated differently, the first step and the second step can be performed in a looping fashion, such that the first step and the second step are alternatingly performed for the time period in the range of from 2 minutes to 20 minutes.

The substrate 110 may be treated at any suitable pressure during operation 11. In one or more embodiments, the first surface 120 and the second surface 130 are treated with the plasma at a pressure in a range of from 50 mTorr to 1,000 mTorr.

In one or more embodiments, in accordance with operation 11 of the method 10, the plasma comprises radicals and ions. In one or more embodiments, the plasma comprises a greater amount of radicals than ions. In one or more embodiments, the plasma comprises a greater amount of ions than radicals.

In one or more embodiments where the plasma comprises a greater amount of radicals than ions, the plasma advantageously removes native oxides isotropically. It has been advantageously found that the plasma comprising a greater amount of radicals than ions removes native oxides from the first surface 120 and facilitates growth of a metal nitride layer 150 on the treated first surface 120′.

In one or more embodiments where the plasma comprises a greater amount of ions than radicals and a bias power in a range of from 0 watts to 500 watts is applied, the plasma advantageously removes native oxides anisotropically.

Referring to FIGS. 1A and 1E, after, at operation 11, treating the substrate 110 (e.g., the first surface 120 and the second surface 130) to form the treated first surface 120′ and the treated second surface 130′, the method 10 includes selectively depositing a metal nitride layer 150 on the treated first surface 120′. In some embodiments, the metal nitride layer 150 is selectively deposited directly on the treated first surface 120′.

The metal nitride layer 150 is selectively deposited on the first surface by exposing the first surface to a metallic precursor and a nitrogen-containing reactant comprising one or more of nitrogen (N₂) or ammonia (NH₃) carried in argon (Ar) or helium (He).

The metallic precursor can be any suitable metal-containing precursor to for form varying metal nitride layers. In some embodiments, the metal-containing precursor comprises a metal halide precursor. In some embodiments, the metal-containing precursor comprises silicon (i.e., a silicon-containing precursor). In some embodiments, the metal-containing precursor comprises aluminum (i.e., an aluminum-containing precursor) In some embodiments, the metal-containing precursor comprises titanium (i.e., a titanium-containing precursor). In some embodiments, the metal-containing precursor comprises tantalum (i.e., a tantalum-containing precursor). In some embodiments, the metal-containing precursor comprises tungsten (i.e., a tungsten-containing precursor).

Accordingly, in some embodiments, the metal nitride layer 150 comprises silicon nitride. In some embodiments, the metal nitride layer 150 comprises aluminum nitride. In some embodiments, the metal nitride layer 150 comprises titanium nitride. In some embodiments, the metal nitride layer 150 comprises tantalum nitride. In some embodiments, the metal nitride layer 150 comprises tungsten nitride.

In some embodiments, where the metal nitride layer 150 comprises silicon nitride, for example, the silicon-containing precursor comprises one or more of silicon tetrachloride (SiCl₄), silicon tetrabromide (SiBr₄), silicon tetraiodide (SiI₄), dichlorosilane (DCS), hexachlorodisilane (HCDS), or octachlorotrisilane (OCTS).

Advantageously, the method 10 achieves selective deposition of the metal nitride layer 150 on the treated first surface 120′ over the treated second surface 130′. The method 10 advantageously provides selective deposition of the metal nitride layer 150 on the treated first surface 120′ over the treated second surface 130′ without the use of an inhibitor.

The metal nitride layer 150 can be selectively deposited on the treated first surface 120′ by any suitable deposition technique. In one or more embodiments, the metal nitride layer 150 is selectively deposited on the treated first surface 120′ by a thermal process (without the use of plasma). In one or more embodiments, the metal nitride layer 150 is selectively deposited on the treated first surface 120′ by thermal chemical vapor deposition (CVD). In one or more embodiments, the metal nitride layer 150 is selectively deposited on the treated first surface 120′ by thermal atomic layer deposition (ALD).

The metal nitride layer 150 can be selectively deposited on the treated first surface 120′ at any suitable deposition temperature. In some embodiments, the metal nitride layer 150 is selectively deposited on the treated first surface 120′ at a deposition temperature in a range of from 200° C. to 500° C.

The metal nitride layer 150 may have any suitable thickness. In one or more embodiments, the metal nitride layer 150 has a thickness that is greater on the treated first surface 120′ than on the treated second surface 130′.

In one or more embodiments, the metal nitride layer 150 has a thickness in a range of from 10 Angstroms to 150 Angstroms on the treated first surface 120′ and a thickness of less than or equal to 5 Angstroms on the treated second surface 130′. In one or more embodiments, as a result of the treatment process of operation 11, the metal nitride layer 150 has a greater binding affinity for the treated first surface 120′ over the treated second surface 130′. In one or more embodiments, the metal nitride layer 150 has a thickness in a range of from 10 Angstroms to 150 Angstroms on the treated first surface 120′, and the metal nitride layer 150 does not form on the treated second surface 130′. In some embodiments, the metal nitride layer 150 is deposited in a single ALD cycle. In other embodiments, the metal nitride layer 150 is deposited in a plurality of ALD cycles.

In one or more embodiments, the method 10 comprises, consists essentially of, or consists of operation 11 and operation 12. One or more of the operations of the method 10 can be repeated any suitable number of times depending on the specific application.

The method 10 can be performed in any suitable processing system. In some embodiments, treating the first surface 120 and the second surface 130 with the plasma (operation 11) and selectively depositing the metal nitride layer (operation 12) are performed in the same processing system.

It will be appreciated by the skilled artisan that one or more additional operations, such as, for example, an optional post-processing operation needed to complete the processing of substrates are known to the skilled artisan and are within the scope of the disclosure without undue experimentation.

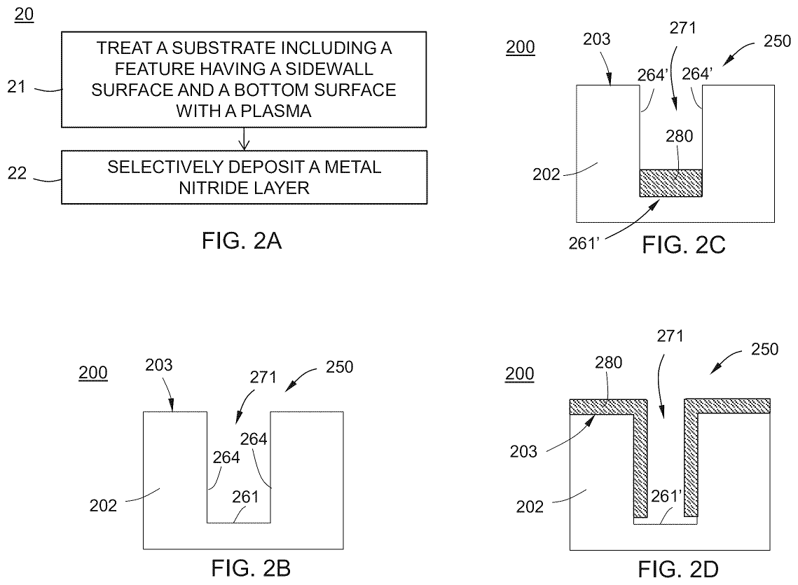

Additional embodiments of the plasma treatment processes for selective deposition are described with reference to FIGS. 2A-2D.

FIG. 2A illustrates a process flow diagram of a method 20. The method 20 is representative of a portion of a method of manufacturing an electronic device 200.

In one or more embodiments, the method 20 comprises, at operation 21, treating a substrate 202 having at least one feature 250 defining a gap 271 having sidewalls 264 and a bottom surface 261 (shown in FIG. 2B). The Figures show substrates 202 having a single feature for illustrative purposes; however, those skilled in the art will understand that there can be more than one feature.

As used herein, the term “feature” means any intentional surface irregularity. Suitable examples of features include but are not limited to trenches which have a top, two sidewalls and a bottom, peaks which have a top and two sidewalls. Features can have any suitable aspect ratio (ratio of the depth of the feature to the width of the feature). In some embodiments, the aspect ratio is greater than or equal to about 5:1, 10:1, 15:1, 20:1, 25:1, 30:1, 35:1, 40:1, 50:1, 100:1, 125:1, or 500:1.

The features described herein can extend vertically into the substrate and/or laterally within the substrate. Unless specifically indicated otherwise, the features described herein are not limited to either of a vertically extending feature or a laterally extending feature. In one or more embodiments, the substrate comprises at least one vertically extending feature. In one or more embodiments, the substrate comprises at least one laterally extending feature. In one or more embodiments, the substrate comprises at least one vertically extending feature and at least one laterally extending feature.

In some embodiments, the at least one feature 250 defines a trench having a top surface 203, the sidewalls 264, and the bottom surface 261.

The sidewalls 264 can include any suitable material. In one or more embodiments, the sidewalls 264 comprise a low-κ dielectric material. In one or more embodiments, the sidewalls 264 comprise a metal oxide. In one or more embodiments, the sidewalls 264 comprise one or more of silicon oxide, aluminum oxide, hafnium oxide, or zirconium oxide. In one or more embodiments, the sidewalls 264 comprise silicon oxide.

In one or more embodiments, the sidewalls 264 comprise one or more of silicon, silicon oxynitride, silicon nitride, tungsten, or titanium aluminum carbide. In one or more embodiments, the sidewalls 264 comprise silicon and silicon oxynitride. In one or more embodiments, the sidewalls 264 comprise silicon and silicon nitride. In one or more embodiments, the sidewalls 264 comprise silicon, silicon oxynitride, and silicon nitride. In one or more embodiments, the sidewalls 264 comprises silicon.

The bottom surface 261 can include any suitable material. In one or more embodiments, the bottom surface 261 comprises one or more of silicon, silicon oxynitride, silicon nitride, tungsten, or titanium aluminum carbide. In one or more embodiments, the bottom surface 261 comprises silicon and silicon oxynitride. In one or more embodiments, the bottom surface 261 comprises silicon and silicon nitride. In one or more embodiments, the bottom surface 261 comprises silicon, silicon oxynitride, and silicon nitride. In one or more embodiments, the bottom surface 261 comprises silicon.

In one or more embodiments, the bottom surface 261 comprises a low-κ dielectric material. In one or more embodiments, the bottom surface 261 comprises a metal oxide. In one or more embodiments, the bottom surface 261 comprises one or more of silicon oxide, aluminum oxide, hafnium oxide, or zirconium oxide. In one or more embodiments, the bottom surface 261 comprises silicon oxide.

In one or more embodiments, the top surface 203 comprises a metallic material. In one or more embodiments, the top surface 203 comprises one or more of copper (Cu), cobalt (cobalt), ruthenium (Ru), tungsten (W), molybdenum (Mo), or titanium aluminum carbide (TiAlC).

With reference to FIGS. 2A-2D, treating the substrate 202 in accordance with operation 21 forms a treated sidewall surface 264′ and a treated bottom surface 261′. In one or more embodiments, treating the substrate 202 in accordance with operation 21 of the method 20 is the same process as treating the substrate 110 in accordance with operation 11 of the method 10.

Referring to FIGS. 2A and 2C, after treating the substrate 202 to form the treated sidewall surface 264′ and the treated bottom surface 261′, the method 20 includes selectively depositing a metal nitride layer 280 on the treated bottom surface 261′ at operation 22. In some embodiments, the metal nitride layer 280 is selectively deposited directly on the treated bottom surface 261′. In one or more embodiments, the metal nitride layer 280 does not form on the treated sidewall surface 264′.

Referring still to FIG. 2C, in one or more embodiments, the treated sidewall surface 264′ comprises a metal oxide, such as one or more of silicon oxide, aluminum oxide, hafnium oxide, or zirconium oxide, and the treated bottom surface 261′ comprises one or more of silicon, silicon oxynitride, silicon nitride, tungsten, or titanium aluminum carbide. In one or more embodiments, the treated sidewall surface 264′ comprises silicon oxide and the treated bottom surface 261′ comprises silicon. In FIG. 2C, the metal nitride layer 280 is selectively deposited on the treated bottom surface 261′ (i.e., one or more of silicon, silicon oxynitride, silicon nitride, tungsten, or titanium aluminum carbide) at operation 22.

Referring to FIGS. 2A and 2D, after treating the substrate 202 to form the treated sidewall surface 264′ and the treated bottom surface 261′, the method 20 includes selectively depositing a metal nitride layer 280 on the treated sidewall surface 264′ at operation 22. In some embodiments, the metal nitride layer 280 is selectively deposited directly on the treated sidewall surface 264′. In one or more embodiments, the metal nitride layer 280 does not form on the treated bottom surface 261′.

Referring still to FIG. 2D, in one or more embodiments, the treated sidewall surface 264′ comprises silicon, silicon oxynitride, silicon nitride, tungsten, or titanium aluminum carbide, and the treated bottom surface 261′ comprises a metal oxide, such as one or more of silicon oxide, aluminum oxide, hafnium oxide, or zirconium oxide. In one or more embodiments, the treated sidewall surface 264′ comprises silicon and the treated bottom surface 261′ comprises silicon oxide. In FIG. 2D, the metal nitride layer 280 is selectively deposited on the treated sidewall surface 264′ (i.e., one or more of silicon, silicon oxynitride, silicon nitride, tungsten, or titanium aluminum carbide) at operation 22. In one or more embodiments, the nitride layer 280 also forms on the top surface 203 at operation 22.

In one or more embodiments, selective depositing the metal nitride layer 280 in accordance with operation 22 of the method 20 is the same process as selective depositing the metal nitride layer 150 in accordance with operation 12 of the method 10.

In one or more embodiments, the metal nitride layer 280 has the same properties as the metal nitride layer 150.

In one or more embodiments, when the substrate 202 is not treated in accordance with the plasma treatment processes herein, the deposition of the metal nitride layer 280 is substantially conformal, such that the metal nitride layer 280 forms at least on the sidewalls 264 and the bottom surface 261. As used herein, a layer which is “substantially conformal” refers to a layer where the thickness is about the same throughout (e.g., on the top surface 203, middle and bottom of sidewalls 264 and on the bottom surface 261). A layer which is substantially conformal varies in thickness by less than or equal to about 5%, 2%, 1% or 0.5%.

The metal nitride layer 280 may have any suitable thickness.

Referring again to FIG. 2C, in one or more embodiments, the metal nitride layer 280 has a thickness in a range of from 10 Angstroms to 150 Angstroms on the treated bottom surface 261′ and a thickness of less than or equal to 5 Angstroms on the treated sidewall surface 264′. In one or more embodiments, the metal nitride layer 280 has a thickness in a range of from 10 Angstroms to 150 Angstroms on the treated bottom surface 261′, and the metal nitride layer 280 does not form on the treated sidewall surface 264′.

Referring again to FIG. 2D, in one or more embodiments, the metal nitride layer 280 has a thickness in a range of from 10 Angstroms to 150 Angstroms on the treated sidewall surface 264′ and the top surface 203, and a thickness of less than or equal to 5 Angstroms on the treated bottom surface 261′. In one or more embodiments, the metal nitride layer 280 has a thickness in a range of from 10 Angstroms to 150 Angstroms on the treated sidewall surface 264′, and the metal nitride layer 280 does not form on the treated bottom surface 261′.

In some embodiments, the metal nitride layer 280 is deposited in a single ALD cycle. In other embodiments, the metal nitride layer 280 is deposited in a plurality of ALD cycles.

In one or more embodiments, the method 20 comprises, consists essentially of, or consists of operation 21 and operation 22. One or more of the operations of the method 20 can be repeated any suitable number of times depending on the specific application.

The method 20 can be performed in any suitable processing system. In some embodiments, treating the substrate 202 with the plasma (operation 21) and selectively depositing the metal nitride layer (operation 22) are performed in the same processing system.

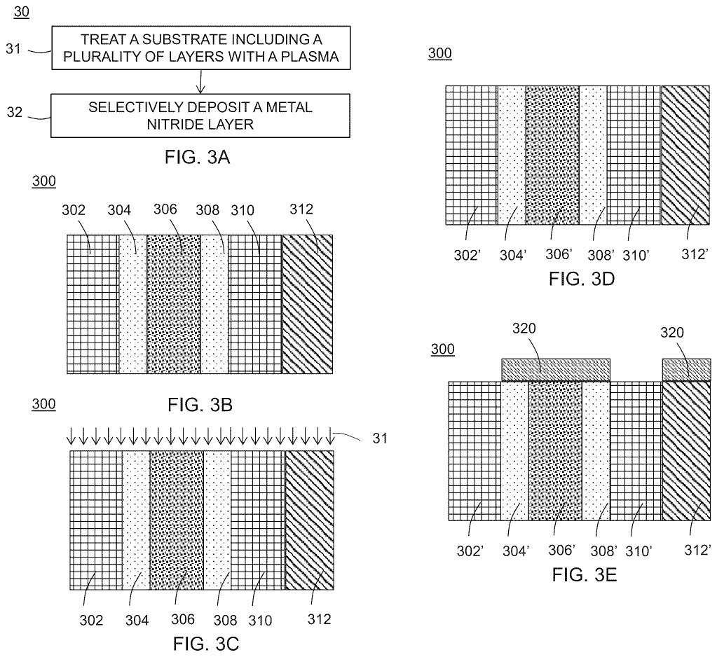

Further embodiments of the plasma treatment processes for selective deposition are described with reference to FIGS. 3A-3E.

FIG. 3A illustrates a process flow diagram of a method 30. FIGS. 3B-3E illustrate stages of processing a substrate 300 in accordance with the method 30. In one or more embodiments, the method 30 comprises, at operation 31, treating the substrate 300 including a plurality of layers with a plasma.

The substrate 300 shown in FIGS. 3B-3E comprises a plurality of layers. In some embodiments, the plurality of layers includes at least a first layer 302 comprising a metal oxide, such as, for example, one or more of silicon oxide, aluminum oxide, hafnium oxide, or zirconium oxide, a second layer 304 comprising one or more of silicon, silicon oxynitride, silicon nitride, tungsten, or titanium aluminum carbide adjacent the first layer 302, a third layer 306 comprising one or more of silicon, silicon oxynitride, silicon nitride, tungsten, or titanium aluminum carbide adjacent the second layer 304, a fourth layer 308 comprising one or more of silicon, silicon oxynitride, silicon nitride, tungsten, or titanium aluminum carbide adjacent the third layer 306, a fifth layer 310 comprising a metal oxide, such as, for example, one or more of silicon oxide, aluminum oxide, hafnium oxide, or zirconium oxide adjacent the fourth layer 308, and a sixth layer 312 comprising one or more of silicon, silicon oxynitride, silicon nitride, tungsten, or titanium aluminum carbide adjacent the fifth layer 310.

In some embodiments, the first layer 302 comprises silicon oxide, the second layer 304 comprises silicon oxynitride, the third layer 306 comprises tungsten, the fourth layer 308 comprises silicon oxynitride, the fifth layer 310 comprises silicon oxide, and the sixth layer 312 comprises silicon nitride.

The plurality of layers may include one or more layers in addition to the first layer 302, the second layer 304, the third layer 306, the fourth layer 308, the fifth layer 310, and the sixth layer 312.

The first layer 302, the second layer 304, the third layer 306, the fourth layer 308, the fifth layer 310, and the sixth layer 312 may each independently have any suitable thickness.

With reference to FIGS. 3A-3E, treating the substrate 300 in accordance with operation 31 forms a treated first layer 302′, a treated second layer 304′, a treated third layer 306′, a treated fourth layer 308′, a treated fifth layer 310′, and a treated sixth layer 312′. The treated first layer 302′, the treated second layer 304′, the treated third layer 306′, the treated fourth layer 308′, the treated fifth layer 310′, and the treated sixth layer 312′ are shown in FIG. 3D after treating the substrate 300 in accordance with operation 31.

In one or more embodiments, treating the substrate 300 in accordance with operation 31 is the same process as treating the substrate 202 in accordance with operation 21 of the method 20, and treating the substrate 110 in accordance with operation 11 of the method 10.

Referring to FIGS. 3A and 3E, after treating the substrate 300 at operation 31, the method 30 includes selectively depositing a metal nitride layer 320.

In one or more embodiments, selective depositing the metal nitride layer 320 in accordance with operation 32 of the method 30 is the same process as selective depositing the metal nitride layer 280 in accordance with operation 22 of the method 20, and selective depositing the metal nitride layer 150 in accordance with operation 12 of the method 10. In one or more embodiments, the metal nitride layer 320 has the same properties as the metal nitride layer 280 and/or the metal nitride layer 150.

In accordance with operation 32 of the method 30, the metal nitride layer 320 is selectively deposited on the treated second layer 304′, the treated third layer 306′, the treated fourth layer 308′, and the treated sixth layer 312′. In one or more embodiments, the metal nitride layer 320 does not form on the treated first layer 302′ or the treated fifth layer 310′.

In accordance with operation 32 of the method 30, in specific embodiments, the metal nitride layer 320 is selectively deposited on the treated second layer 304′ (one or more of silicon, silicon oxynitride, silicon nitride, tungsten, or titanium aluminum carbide), the treated third layer 306′ (one or more of silicon, silicon oxynitride, silicon nitride, tungsten, or titanium aluminum carbide), the treated fourth layer 308′ (one or more of silicon, silicon oxynitride, silicon nitride, tungsten, or titanium aluminum carbide), and the treated sixth layer 312′ (one or more of silicon, silicon oxynitride, silicon nitride, tungsten, or titanium aluminum carbide). In specific embodiments, the metal nitride layer 320 does not form on the treated first layer 302′ (one or more of silicon oxide, aluminum oxide, hafnium oxide, or zirconium oxide) or the treated fifth layer 310′ (one or more of silicon oxide, aluminum oxide, hafnium oxide, or zirconium oxide).

In accordance with operation 32 of the method 30, in specific embodiments, the metal nitride layer 320 is selectively deposited on the treated second layer 304′ (silicon oxynitride), the treated third layer 306′ (tungsten), the treated fourth layer 308′ (silicon oxynitride), and the treated sixth layer 312′ (silicon nitride). In specific embodiments, the metal nitride layer 320 does not form on the treated first layer 302′ (silicon oxide) or the treated fifth layer 310′ (silicon oxide).

In one or more embodiments, the method 30 comprises, consists essentially of, or consists of operation 31 and operation 32. One or more of the operations of the method 30 can be repeated any suitable number of times depending on the specific application.

The method 30 can be performed in any suitable processing system. In some embodiments, treating the substrate 300 with the plasma (operation 31) and selectively depositing the metal nitride layer (operation 32) are performed in the same processing system.

In one or more embodiments, the methods described herein comprise an optional post-processing operation. The optional post-processing operation can be, for example, a process to modify film properties (e.g., annealing) or a further film deposition process (e.g., additional ALD or CVD processes) to grow additional films. In some embodiments, the optional post-processing operation can be a process that modifies a property of the deposited film/layer.

In some embodiments, the optional post-processing operation comprises annealing the substrate. In some embodiments, the annealing process is performed at temperatures in the range of from 300° C. to 1000° C. The annealing environment of some embodiments comprises one or more of an inert gas (e.g., molecular nitrogen (N₂), argon (Ar)) or a reducing gas (e.g., molecular hydrogen (H₂) or ammonia (NH₃)) or an oxidant, such as, but not limited to, oxygen (O₂), ozone (O₃), or peroxides. Annealing can be performed for any suitable length of time. In some embodiments, the substrate is annealed for a predetermined time in the range of about 15 seconds to about 90 minutes, or in the range of about 1 minute to about 60 minutes. In some embodiments, annealing the substrate increases the density, decreases the resistivity and/or increases the purity of the layers.

In one or more embodiments, one or more of the operations of the methods described herein are performed in situ, without an intervening vacuum break. In one or more embodiments, each of the operations of the methods described are performed in situ, without an intervening vacuum break. In one or more embodiments, one or more of the operations of the methods described herein are performed ex situ, such that one or more of the processes are performed with an intervening vacuum break.

The methods described herein can be performed any suitable processing system. The particular arrangement of processing chambers and components in the processing system can be varied depending on the processing system and should not be taken as limiting the scope of the disclosure.

Processes may generally be stored in the memory of a system controller as a software routine that, when executed by the processor, causes the processing system to perform one or more of the operations of any of the methods described herein. The software routine may also be stored and/or executed by a second processor (not shown) that is remotely located from the hardware being controlled by the processor. Some or all of the methods of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the processing system operation such that one or more of the operations of any of the methods described herein are performed.

One or more embodiments of the disclosure are directed to a non-transitory computer readable medium including instructions that, when executed by a controller of a processing system, causes the processing system to perform one or more of the operations of any of the methods described herein.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method comprising:
selectively depositing a metal nitride layer on a first surface comprising one or more of silicon, silicon oxynitride, silicon nitride, tungsten, or titanium aluminum carbide, over a second surface comprising one or more of silicon oxide, aluminum oxide, hafnium oxide, or zirconium oxide, wherein the first surface and the second surface are treated with a plasma prior to selectively depositing the metal nitride layer.

2. The method of claim 1, wherein the plasma is configured to remove native oxides from the first surface and the second surface.

3. The method of claim 1, wherein treating the second surface with the plasma is configured to substantially prevent deposition of the metal nitride layer on the second surface.

4. The method of claim 1, wherein the plasma is generated by one or more of a microwave plasma source, a remote plasma source, an inductively coupled plasma (ICP) source, or a capacitively coupled plasma (CCP) source.

5. The method of claim 4, wherein the plasma is generated at a source power in a range of from 100 watts to 1,500 watts.

6. The method of claim 1, wherein the first surface and the second surface are treated with the plasma at a bias power in a range of from 0 watts to 500 watts.

7. The method of claim 1, wherein the first surface and the second surface are treated with the plasma at a pressure in a range of from 50 mTorr to 1,000 mTorr.

8. The method of claim 1, wherein the first surface and the second surface are treated with the plasma at a first temperature for a first time period, followed by a second temperature for a second time period, the second temperature greater than the first temperature.

9. The method of claim 8, wherein the first temperature is in a range of from 20° C. to 50° C.

10. The method of claim 8, wherein the second temperature is in a range of from 90° C. to 200° C.

11. The method of claim 1, wherein the plasma comprises radicals and ions.

12. The method of claim 11, wherein the plasma comprises a greater amount of radicals than ions.

13. The method of claim 1, wherein the plasma comprises one or more of hydrogen (H₂), helium (He), argon (Ar), carbon tetrafluoride (CF₄), nitrogen trifluoride (NF₃), trifluoromethane (CHF₃), chlorine trifluoride (ClF₃), difluoromethane (CH₂F₂), hexafluoro-1,3-butadiene (C₄F₆), sulfur hexafluoride (SF₆), octafluorocyclobutane (C₄F₈), chlorine (Cl₂), boron trichloride (BCl₃), bromotrifluoromethane (CF₃Br), hydrogen bromide (HBr), or ammonia (NH₃).

14. The method of claim 1, wherein the metal nitride layer is selectively deposited on the first surface by thermal atomic layer deposition (ALD) at a deposition temperature in a range of from 200° C. to 500° C.

15. The method of claim 14, wherein the metal nitride layer is selectively deposited on the first surface by exposing the first surface to a metallic precursor and a nitrogen-containing reactant comprising one or more of nitrogen (N₂) or ammonia (NH₃) carried in argon (Ar) or helium (He).

16. The method of claim 15, wherein the metal nitride layer comprises silicon nitride and the metallic precursor is a silicon-containing precursor.

17. The method of claim 16, wherein the silicon-containing precursor comprises one or more of silicon tetrachloride (SiCl₄), silicon tetrabromide (SiBr₄), silicon tetraiodide (SiI₄), dichlorosilane (DCS), hexachlorodisilane (HCDS), or octachlorotrisilane (OCTS).

18. The method of claim 1, wherein treating the first surface and the second surface with the plasma and selectively depositing the metal nitride layer are performed in the same processing system.

19. A method comprising:
selectively depositing a metal nitride layer on a substrate having at least one feature defining a gap having sidewalls and a bottom surface, the sidewalls comprising one or more of silicon oxide, aluminum oxide, hafnium oxide, or zirconium oxide, the bottom surface comprising one or more of silicon, silicon oxynitride, silicon nitride, tungsten, or titanium aluminum carbide, wherein the substrate is treated with a plasma prior to selectively depositing the metal nitride layer, and the metal nitride layer is selectively deposited on the bottom surface over the sidewalls.

20. A method comprising:
selectively depositing a metal nitride layer on a substrate comprising a plurality of layers, the plurality of layers including a first layer comprising one or more of silicon oxide, aluminum oxide, hafnium oxide, or zirconium oxide, a second layer comprising one or more of silicon, silicon oxynitride, silicon nitride, tungsten, or titanium aluminum carbide adjacent the first layer, a third layer comprising one or more of silicon, silicon oxynitride, silicon nitride, tungsten, or titanium aluminum carbide adjacent the second layer, a fourth layer comprising one or more of silicon, silicon oxynitride, silicon nitride, tungsten, or titanium aluminum carbide adjacent the third layer, a fifth layer comprising one or more of silicon oxide, aluminum oxide, hafnium oxide, or zirconium oxide adjacent the fourth layer, and a sixth layer comprising one or more of silicon, silicon oxynitride, silicon nitride, tungsten, or titanium aluminum carbide adjacent the fifth layer, wherein the substrate is treated with a plasma prior to selectively depositing the metal nitride layer, and the metal nitride layer is selectively deposited on the second layer, the third layer, the fourth layer, and the sixth layer over the first layer and the fifth layer.
